(19) United States
(12) Patent Application Publication
(10) Pub. No.: US 2026/0324078 A1
(43) Pub. Date: Oct. 15, 2026

(54) ARRAY SUBSTRATE AND DISPLAY DEVICE

(71) Applicants: Beijing BOE Optoelectronics Technology Co., Ltd., Beijing (CN); BOE Technology Group Co., Ltd., Beijing (CN)

(72) Inventors: Ning WANG, Beijing (CN); Xiaojuan WU, Beijing (CN); Dawei FENG, Beijing (CN); Zhiqiang YU, Beijing (CN); Feng LIU, Beijing (CN); Jiaxing WANG, Beijing (CN); Jinshuai DUAN, Beijing (CN); Cuiyu CHEN, Beijing (CN); Danxing HOU, Beijing (CN); Xiaofeng YIN, Beijing (CN)

(21) Appl. No.: 19/483,170

(22) PCT Filed: May 23, 2024
(86) PCT No.: PCT/CN2024/095015

§ 371 Date: Nov. 10, 2025

(30) Foreign Application Priority Data
May 26, 2023 (CN) 202310614789.9

(51) Int. Cl. H10D 86/40; G02F 1/1333; G02F 1/1339

(52) U.S. Cl. CPC H10D 86/441; G02F 1/13338; G02F 1/1339

(57) ABSTRACT

An array substrate includes a base substrate, touch lines, signal lines, a touch module, and support members. The base substrate includes a display region, a first sealing region, a second sealing region, and two third sealing regions. The first sealing region and the second sealing region are disposed on two opposite sides of the display region in a first direction, the two third sealing regions are disposed on two opposite sides of the display region in a second direction, and the first direction is perpendicular to the second direction. The touch module is disposed on a side of the second sealing region away from the display region, the touch lines extend in the second direction in the display region, the signal lines are disposed in the second sealing region, and the touch lines are connected to the touch module through the signal lines.

The present disclosure is a US national stage of international application No. PCT/CN2024/095015, filed on May 23, 2024, which claims priority to Chinese Patent Application No. 202310614789.9, filed on May 26, 2023 and entitled “ARRAY SUBSTRATE, DISPLAY PANEL AND DISPLAY DEVICE”, the disclosures of which are incorporated herein by reference in their entireties.

### TECHNICAL FIELD

The present disclosure relates to an array substrate and a display device.

### BACKGROUND

Touch technologies have gradually appeared around the public, and are widely used in electronic products such as office tablets, writing pads, and drawing tablets.

During the manufacturing process of a touch product of a liquid crystal display (LCD) panel, the formation of a liquid crystal cell is very important, especially the design of the cell gap. In order to obtain an accurate and uniform cell gap, in addition to controlling the height of the display region of the array substrate in the LCD touch product, it is also very important to design the height of the non-display region of the array substrate.

### SUMMARY

The present disclosure provides an array substrate and a display device, which can improve the cell gap uniformity of the display device.

In a first aspect, the present disclosure provides an array substrate, which includes: a base substrate, a plurality of touch lines, a plurality of signal lines, a touch module, and support members; where
the base substrate includes a display region, a first sealing region, a second sealing region, and two third sealing regions, the first sealing region and the second sealing region are disposed on two opposite sides of the display region in a first direction, the two third sealing regions are disposed on two opposite sides of the display region in a second direction, and the first direction is perpendicular to the second direction; the touch module is disposed on a side of the second sealing region away from the display region, the touch lines are disposed in the display region, the signal lines are disposed in the second sealing region, and the touch lines are connected to the touch module through the signal lines; and
the support members are distributed in the first sealing region and/or the two third sealing regions, the support members and the signal lines are disposed in a same layer, and in a direction perpendicular to the base substrate, a difference between a thickness of each of the support members and a thickness of each of the signal lines is less than the thickness of the signal line.

Optionally, a ratio of the thickness of each of the support members to the thickness of each of the signal lines is greater than 0.8 and less than 1.2.

Optionally, the thickness of each of the support members is as same as the thickness of each of the signal lines.

Optionally, a material of each of the support members is as same as a material of each of the signal lines.

Optionally, an area ratio of the support members in the first sealing region and an area ratio of each of the support members in the third sealing regions are all greater than 0.2 and less than 1.

Optionally, the support members are further distributed in the second sealing region, and an orthographic projection of each of the support members on the base substrate is disposed outside an orthographic projection of each of the signal lines on the base substrate.

Optionally, in the second sealing region, the support members are distributed on two sides of the signal lines.

Optionally, an area ratio of the support members in the second sealing region is greater than 0.1 and less than 0.6.

Optionally, a plurality of the support members are provided and spaced apart from each other in at least one sealing region where the support members are disposed.

Optionally, the support members are arranged in an array in the at least one sealing region.

Optionally, the support members in the first sealing region are strip-shaped, extend in the second direction, and are spaced apart in the first direction.

Optionally, the support members in the first sealing region are strip-shaped, extend in the first direction, and are spaced apart in the second direction.

Optionally, the support members in the second sealing region are strip-shaped, extend in the first direction, and are spaced apart in the second direction.

Optionally, the plurality of touch lines extend in the second direction and are spaced apart in the first direction;
the array substrate further includes: common lines, each of the common lines extends in the first direction in each of the two third sealing regions; a plurality of the support members are distributed in each of the two third sealing regions, and the plurality of support members are spaced apart in the first direction and extend in the second direction; the plurality of support members in each of the two third sealing regions are disposed between each of the common lines and the display region; and
the plurality of support members are in a one-to-one correspondence with the plurality of touch lines, and an end of each of the plurality of support members close to the display region is connected to a corresponding touch line, and an end of each of the plurality of support members away from the display region is connected to each of the common lines.

Optionally, the array substrate further includes gate drive circuits, and each of the gate drive circuits is disposed between the display region and each of the two third sealing regions.

Optionally, the plurality of touch lines extend in the second direction and are spaced apart in the first direction; and the array substrate further includes: common lines, each of the common lines extends in the first direction between the each of the third sealing regions and the display region; and an end of each of the plurality of touch lines close to the common line is connected to the common line.

Optionally, the array substrate further includes: gate drive circuits, each of the gate drive circuits is disposed on a side of each of the common lines away from the display region, and at least a portion of an orthographic projection of each of the gate drive circuits on the base substrate is disposed in each of the two third sealing regions.

Optionally, the plurality of touch lines extend in the second direction and are spaced apart in the first direction; and the signal lines and the touch lines satisfy at least one of following conditions:
the signal lines and the touch lines are disposed in a same layer;
the thickness of each of the signal lines is as same as a thickness of each of the touch lines; and
the material of each of the signal lines is as same as a material of each of the touch lines.

Optionally, overlapping metal wires are provided in the at least one sealing region in which the support members are disposed, and an orthographic projection of each of the support members on the base substrate is disposed outside an orthographic projection of an overlapping portion of the metal wires on the base substrate.

In a second aspect, the present disclosure provides a display device, which includes: an array substrate and a color filter substrate, and a liquid crystal layer and a sealant disposed between the array substrate and the color filter substrate; where
the array substrate is the array substrate according to any one of the embodiments of the first aspect, and the sealant is disposed in the first sealing region, the second sealing region, and the third sealing regions of the array substrate.

### BRIEF DESCRIPTION OF DRAWINGS

FIG. 1 is a schematic diagram of a jumper design in the related art;

FIG. 2 is a schematic structural diagram of an array substrate according to some embodiments of the present disclosure;

FIG. 3 is a schematic diagram of a thickness of a signal line and a thickness of a support member according to the present disclosure;

FIG. 4 is a schematic structural diagram of another array substrate according to some embodiments of the present disclosure;

FIG. 5 is a schematic structural diagram of still another array substrate according to some embodiments of the present disclosure;

FIG. 6 is a schematic diagram of a position relationship among metal wires and third support members according to some embodiments of the present disclosure;

FIG. 7 is a schematic diagram of horizontal touch lines and a vertical touch line according to some embodiments of the present disclosure;

FIG. 8 is a schematic structural diagram of still another array substrate according to some embodiments of the present disclosure;

FIG. 9 is a schematic structural diagram of still another array substrate according to some embodiments of the present disclosure; and

FIG. 10 is a schematic diagram of a display device according to some embodiments of the present disclosure.

### DETAILED DESCRIPTION

In order to make the principles, technical solutions and advantages of the present disclosure clearer, the present disclosure will be further described in detail below with reference to specific embodiments and the accompanying drawings.

Unless otherwise defined, the technical or scientific terms used in the embodiments disclosed herein should be understood in the general sense by those of ordinary skill in the art to which the present disclosure belongs. The terms “first”, “second”, and other similar words, as used in the present disclosure, do not indicate any order, quantity, or importance, but are merely defined to distinguish different components. The terms “include”, “comprise”, or other similar words indicate that the elements or objects stated before them encompass the elements or objects and equivalents thereof listed after them, but do not exclude other elements or objects. The terms “connecting”, “connected”, or other similar words are not limited to physical or mechanical connections, but may include electrical connections, whether direct or indirect. The terms “up”, “down”, “left”, “right”, and the like are merely defined to indicate relative positional relationships. In the case that the absolute position of a described object changes, the relative positional relationships may also change accordingly.

With the development of the era, touch technologies have gradually appeared around the public, and are widely used in products such as office tablets, writing pads, and drawing tablets. The touch technologies are applicable to annotation, note-taking, line drawing, and the like in text gaps. The characteristics of the touch technologies, such as high precision, high light transmittance, and high resolution, are well known, and the writing fluency and the response time are increasingly excellent.

During the manufacturing process of the LCD touch product, the formation of the liquid crystal cell is very important. However, the array substrate in the related art may cause the cell gap in the non-display region to be non-uniform, and then cause liquid leakage and moisture intrusion in the LCD touch product, and thus affecting the display effect of the LCD touch product.

In the process of implementing the present disclosure, it was found that an LCD touch product in the related art adopts a 7-mask structure. Compared with a 9-mask structure, the 7-mask structure can improve the aperture ratio. In addition, in the LCD touch product in the related art, a data line is added to each pixel unit as a vertical touch line, and a copper wire is added to each pixel unit as a horizontal touch line. The touch line here may be referred to as an electromagnetic coil. Both the horizontal and vertical touch lines are connected to a touch module in the non-display region, and the touch module determines a touch position based on touch signals on the horizontal and vertical touch lines.

In the related art, the horizontal touch line is a copper wire, the thickness of the copper wire is 9000 angstroms (Å), and the resistance of the copper wire is small, which can increase the signal amount of the horizontal touch line and improve the touch sensitivity. However, the copper wire connected from the display region to a touch module on a drive panel (DP) side in the non-display region needs to pass through a fanout region in the non-display region. A sealant needs to be provided in the fanout region to prevent moisture from corroding the copper wire. However, the 9000 Å copper wire elevates the height of the sealant, which increases the cell gap in the fanout region and reduces the cell gap uniformity in the non-display region of the array substrate.

For example, in the non-display region of the array substrate, the side opposite to the drive panel side (DPO side) and the other two sides except the DP side and the DPO side are provided with sealants without copper wires. The sealants on the three sides are not elevated, which results that the heights of the sealants on the three sides are lower than the height of the sealant on the DP side, and the cell gaps on the three sides are inconsistent with the cell gap on the DP side and thus the cell gap uniformity in the non-display region is deteriorated.

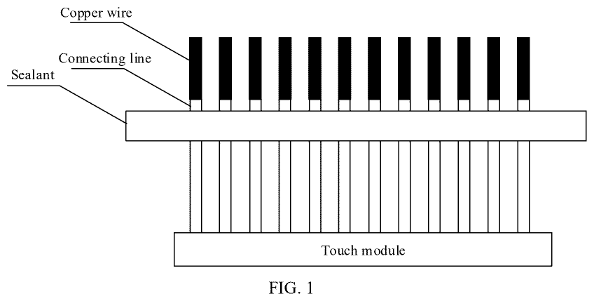

In the related art, a jumper design is used for signal lines in a fanout region. As shown in FIG. 1, copper wires and connecting lines are connected through via holes (the via holes are not shown in the figure), and the copper wires under a sealant are replaced with the connecting lines. Each of the connecting lines is a three-layer stacked structure of molybdenum, aluminum, and molybdenum, and the thickness of the connecting line is 3500 angstroms (Å), which is less than the thickness of the copper wire (9000 angstroms), so as to reduce the elevated height of the sealant.

However, the jumper design decreases the connection performance between the copper wires and the connecting lines, which affects the effective connection between the copper wires and the touch module, and results in a reduction of the touch sensitivity. Moreover, under the jumper design, the sealant is also elevated to a certain extent due to the presence of the connecting lines, so the jumper design has a limited effect on improving the cell gap uniformity.

Based on the above, it can be seen that there is an urgent need for an array substrate that can improve the cell gap uniformity while ensuring the touch sensitivity.

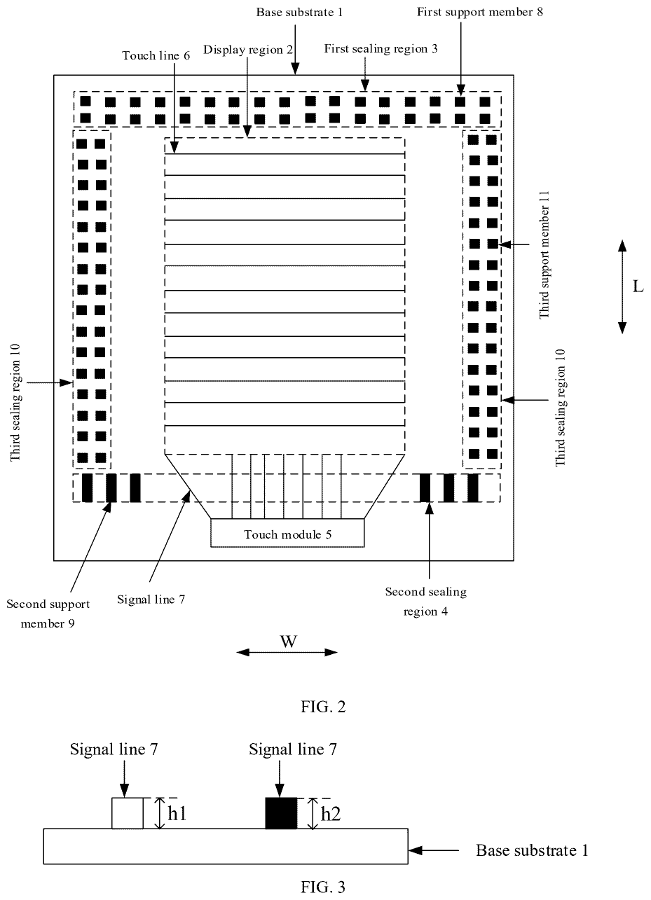

Some embodiments of the present disclosure provide an array substrate. As shown in FIG. 2, the array substrate includes: a base substrate 1, a plurality of touch lines 6, a plurality of signal lines 7, a touch module 5, and support members (such as first support members 8 and second support members 9 in FIG. 2).

Referring to FIG. 2, the base substrate 1 includes a display region 2, a first sealing region 3, a second sealing region 4, and two third sealing regions 10. The first sealing region 3 and the second sealing region 4 are disposed on two opposite sides of the display region 2 in a first direction L, the two third sealing regions 10 are disposed on two opposite sides of the display region 2 in a second direction W, and the first direction L is perpendicular to the second direction W. The side where the first sealing region 3 is disposed is the DPO side, and the side where the second sealing region 4 is disposed is the DP side. The sealing regions are used to coat a sealant 16 to support an array substrate and a color filter substrate and stabilize the cell gap, so as to block or slow down external moisture or impurities from entering the display region 2.

The touch module 5 is disposed on a side of the second sealing region 4 away from the display region 2, the touch lines 6 extend in the second direction W in the display region 2 (it can be seen that the touch lines 6 here are also the aforementioned horizontal touch lines), the signal lines 7 are disposed in the second sealing region 4, and the touch lines 6 are connected to the touch module 5 through the signal lines 7. A connection relationship between the touch lines 6 and the signal lines 7 is not shown in FIG. 2. The touch module 5 is an electromagnetic induction flexible printed circuit (EMR FPC), a chip, or the like. The touch module 5 is configured to receive touch signals from the touch lines 6.

In the embodiments of the present disclosure, the support members in the array substrate are distributed in the first sealing region 3 and/or the third sealing regions 10. For example, first support members 8 are distributed in the first sealing region 3, and third support members 11 are distributed in the third sealing regions 10. In the embodiments of the present disclosure, the scenario where the support members are distributed in the first sealing region 3 and the third sealing regions 10 is taken as an example, it can be understood that the support members may be also distributed in the first sealing region 3 or the third sealing regions 10.

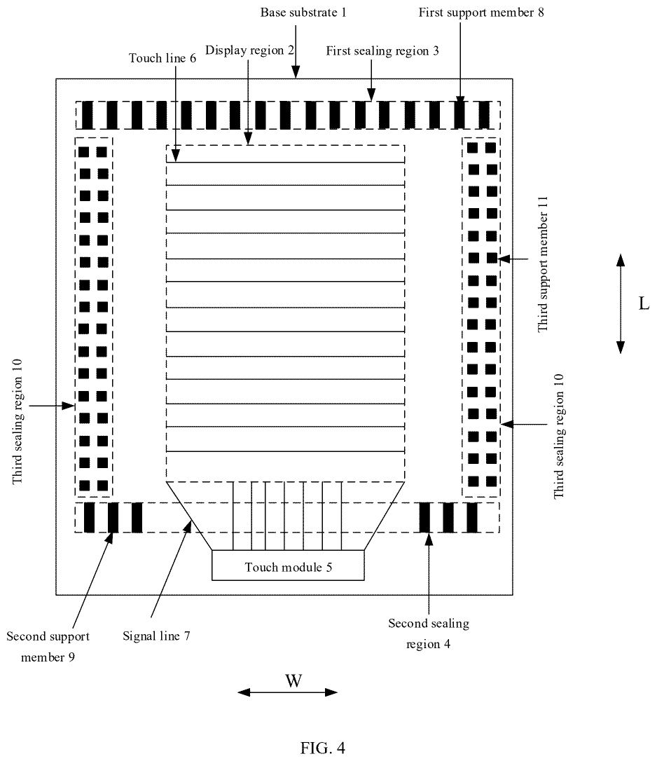

The support members and the signal lines 7 are disposed in a same layer and are in a direction perpendicular to the base substrate 1, and a difference between a thickness of the support member and a thickness of the signal line 7 is less than the thickness of the signal line 7. Exemplarily, a ratio of the thickness of the support member to the thickness of the signal line 7 is greater than 0.8 and less than 1.2. For example, the ratio is 0.8, 0.9, 1.0, 1.1, or 1.2. As shown in FIG. 3, in the direction perpendicular to the base substrate 1, a difference between a thickness h2 of the support member and a thickness h1 of the signal line 7 is less than the thickness h1 of the signal line 7. In FIG. 3, a scenario where h1 is equal to h2 and a ratio of h1 to h2 is 1 is taken as an example. In this case, the difference between h2 and h1 is 0, and 0 is less than h1. It can be understood that h1 may also not be equal to h2 which is not limited in the embodiments of the present disclosure.

The thickness ratio of the support member to the signal line 7 is set to 0.8 to 1.2. This can effectively reduce the cell gap difference in the non-display region, prevent the sealant from being elevated too high and the cell gap from being increased too much due to excessive thickness ratio, thereby reducing the cell gap uniformity. This may also prevent the height of the sealant in other regions from being significantly lower than the height of the sealant at the signal line 7 due to too small thickness ratio, thereby reducing the cell gap uniformity. The thickness of the support member is set to be the same as the thickness of the signal line 7, so as to ensure that the heights of the sealants in the first sealing region 3, the second sealing region 4, and the third sealing regions 10 are consistent, and then ensure that the cell gap is consistent everywhere, improving the cell gap uniformity in the non-display region, and ensuring the display effect.

A thickness ratio of the first support member 8 to the signal line 7, a thickness ratio of the second support member 9 to the signal line 7, and a thickness ratio of the third support member 11 to the signal line 7 may be the same and also may be different.

Since the signal lines 7 are disposed in the second sealing region 4, the in-plane step difference of the second sealing region 4 increases, and thus the height of the sealant coated in the second sealing region 4 is increased and the cell gap at the position where the second sealing region 4 is disposed is increased. In the embodiments of the present disclosure, the first sealing region 3 and the second sealing region 4 are disposed on two opposite sides of the display region 2. By disposing the first support members 8 in the first sealing region 3 (each first support member 8 is, for example, of a block structure, and is disposed between the base substrate 1 and the sealant), the height of the sealant coated in the first sealing region 3 can be increased and then the cell gap of the first sealing region 3 can be increased, and the cell gap difference between the first sealing region 3 and the second sealing region 4 is reduced such that the cell gapes on the two opposite sides of the display device are closer to each other, and the cell gap uniformity of the non-display region is improved, thereby avoiding liquid crystal leakage and water vapor intrusion caused by local elevation of the sealant, and also avoiding undesirable phenomena such as yellowing of the screen caused by the non-uniform cell gap, and improving the quality of the displayed image.

In addition, the two third sealing regions 10 are disposed on two opposite sides of the base substrate 1 in the second direction W, and the third support members 11 (each third support member 11 is, for example, of a block structure) are disposed in the two third sealing regions 10, such that the height of the sealant in the third sealing region 10 can be increased, a cell gap difference between the third sealing region 10 and the second sealing region 4 can be reduced, and the cell gap uniformity in the non-display region can be improved.

On the basis that the third support members 11 cooperate with the first support members 8, an overall cell gap of the non-display region can be further balanced, thereby ensuring the display effect.

The array substrate has a simple structure and is easy to manufacture, which can effectively reduce the cell gap difference in the non-display region, improve the cell gap uniformity, and ensure the display effect.

In some embodiments, the support members are further distributed in the second sealing region, and orthographic projections of the support members on the base substrate 1 are disposed outside orthographic projections of the signal lines 7 on the base substrate 1. The second support members and the signal lines 7 are disposed in a same layer, and in a direction perpendicular to the base substrate 1, a difference between a thickness of each of the second support members and a thickness of each of the signal lines 7 is less than the thickness of each of the signal lines 7. With further reference to FIG. 2, second support members 9 are disposed in the second sealing region 4, the second support members 9 are spaced apart from the signal lines 7, and the second support members 9 can reduce the cell gap difference between the position of the second support members 9 and the position of the signal lines 7.

As shown in FIG. 2, the signal lines 7 pass through the second sealing region 4 and this would elevate a local sealant in the second sealing region 4and result a local cell gap in the second sealing region 4 to be larger. For example, the signal lines 7 pass through the middle of the second sealing region 4 and this would elevate the sealant in the middle of the second sealing region 4, but the sealants at end portions of the second sealing region 4 are low and thus an in-plane step difference is formed and the sealing effect is poor. The second support members 9 (each of the second support members 9 is of, for example, a block structure) are provided in the second sealing region 4, and the second support members 9 are spaced apart from the signal lines 7, the height of the sealant in the region other than the signal lines 7 in the second sealing region 4 can be increased, and the cell gap difference between the position of the second support members 9 and the position of the signal lines 7 can be reduced, such that the cell gap uniformity in the entire second sealing region 4 is increased. It can be understood that the embodiments of the present disclosure take the case where the second support members are distributed in the second sealing region 4 as an example. Certainly, the second sealing region 4 may not be provided with the support members, which is not limited in the embodiments of the present disclosure.

In some embodiments, in the second sealing region 4, the support members are distributed on both sides of the signal lines 7. As shown in FIG. 2, the signal lines 7 pass through the middle of the second sealing region 4, and the second support members 9 are provided at two opposite ends of the second sealing region 4 in the second direction W. In this way, the second support members 9 can further balance the in-plane step difference of the second sealing region 4, thereby improving the cell gap uniformity.

The shape of the support members is not limited in the embodiments of the present disclosure. For example, the support members may be in a block shape, a strip shape, or an irregular shape.

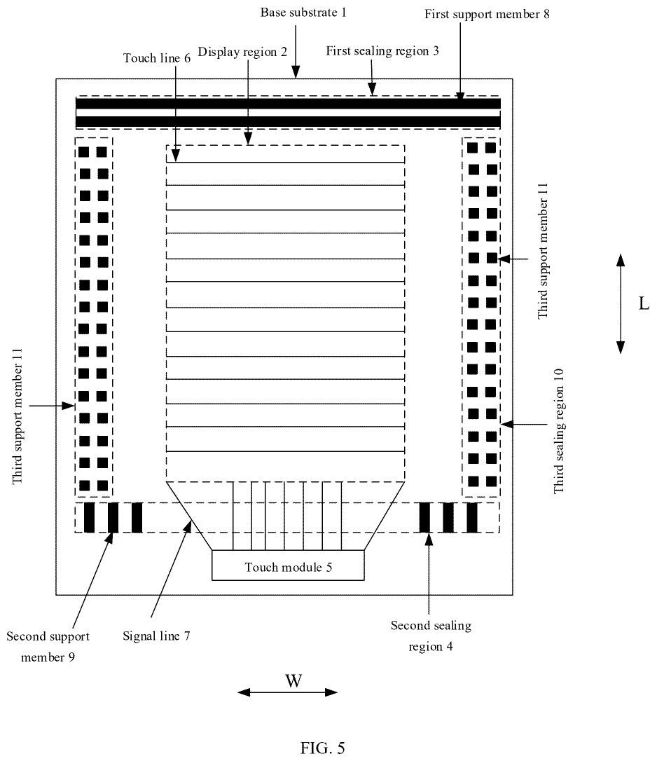

For example, as shown in FIG. 2, the support members (first support members) in the first sealing region 3 are block-shaped and arranged in an array. Or, as shown in FIG. 4, the support members in the first sealing region 3 are strip-shaped, extend in the first direction L, and are spaced apart from each other in the second direction W. Or, as shown in FIG. 5, the support members (first support members) in the first sealing region 3 are strip-shaped, extend in the second direction W, and are spaced apart from each other in the first direction L.

In another example, as shown in FIG. 2, the support members in the second sealing region 4 are strip-shaped, extend in the first direction L, and are spaced apart from each other in the second direction W. Or, the support members (second support members) in the second sealing region 4 are block-shaped and arranged in an array.

In some embodiments, a plurality of the support members are provided and spaced apart from each other in at least one of the first sealing region, the second sealing region, and the third sealing regions in the base substrate. For example, as shown in FIG. 2, a plurality of first support members 8, a plurality of second support members 9, and a plurality of third support members 11 are provided and spaced apart from each other. On this basis, in the at least one sealing region, the support members are arranged in an array.

In the case that a plurality of support members are provided and spaced apart from each other in the at least one sealing region, in each of the at least one sealing region, an interval between two adjacent support members in the first direction L may be 112.8 micrometers (μm), an interval between two adjacent support members in the second direction W may be also 112.8 μm, and in addition, an orthographic projection area of a single support member on the base substrate may be 400 square micrometers (μm²).

In the case that a plurality of support members are provided and spaced apart from each other in the at least one sealing region, the plurality of support members can uniformly increase the height of the sealant in the sealing region where the plurality of support members are disposed, and then balance the cell gap difference in the sealing region. In the at least one sealing region, in the case that the support members are arranged in an array, the cell gap difference in the sealing region can be further balanced. Compared with separately providing a large-area support member in the sealing region, providing a plurality of support members that are spaced apart from each other in the sealing region can reduce material costs of the support members, reduce a strong electrostatic effect generated by the large-area support member, and improve the display effect. In addition, providing a plurality of support members that are spaced apart from each other in the sealing region may also facilitate the support members to avoid conductors (such as gate lines and data lines) in the sealing region, thereby avoiding excessively increasing the cell gap and reducing the cell gap uniformity by providing the support members directly over these conductors cell gap uniformity.

In some embodiments, an area ratio of the support members in the first sealing region 3 and the third sealing region 10 is greater than 0.2 and less than 1, and the area ratio may be 0.2, 0.3, 0.4, 0.5, 0.6, 0.7, 0.8, 0.9, 1.0, or the like. For example, a ratio of a total area of the first support members 8 to an area of the first sealing region 3 is 0.2 to 1, and a ratio of a total area of the third support members 11 to an area of the third sealing region 10 is 0.2 to 1.

In some embodiments, an area ratio of the support members in the second sealing region 4 is greater than 0.1 and less than 0.6, and the area ratio may be 0.2, 0.3, 0.4, 0.5, 0.6, or the like. For example, a ratio of a total area of the second support members 9 to the area of the second sealing region 4 is 0.1 to 0.6.

The area ratio of the first support members 8 to the first sealing region 3 is set to 0.2 to 1, which can effectively support the sealant 16 at the first sealing region 3, prevent insufficient improvement in the cell gap uniformity due to too small area ratio and also prevent increased costs, enhanced electrostatic effect and reduced display effect due to too large area ratio. The area ratio of the second support members 9 to the second sealing region 4 is set to 0.2 to 0.6, because the signal lines 7 occupy a portion of the second sealing region 4, and thus the area ratio is set to be low. In this way, it can effectively support the sealant 16 at the second sealing region 4, prevent insufficient improvement in the cell gap uniformity due to too small area ratio, and it can also prevent increased costs and enhanced electrostatic effect and from being not conducive to bending due to too large area ratio. The area ratio of the third support members 11 to the third sealing region 10 is set to 0.2 to 1, which can effectively support the sealant 16 at the third sealing region 10, prevent insufficient improvement in the cell gap uniformity due to too small area ratio and also prevent increased costs, enhanced electrostatic effect and reduced display effect due to too large area ratio

The support member may be made of a conductive material or an insulating material which is not limited in the embodiments of the present disclosure. In the case that the support member is made of a conductor material, it needs to be ensured that functions of conductors other than the support members in the array substrate are not affected by the arrangement of the support members in the array substrate. For example, the support members need to be insulated from the gate lines and the data lines on the array substrate.

Optionally, the material of the support members is the same as the material of the signal lines 7. For example, the support members and the signal lines 7 are all made of copper. The material of the support members may be also different from the material of the signal lines 7, which is not limited in the embodiments of the present disclosure.

In the case that the material of the support members is the same as the material of the signal lines 7, the thickness of the support members is the same as the thickness of the signal lines 7, and the support members and the signal lines 7 are disposed in the same layer, the support members and the signal lines 7 may be manufactured by using a single patterning process.

Optionally, a plurality of touch lines 6 all extend in the second direction W, and the plurality of touch lines 6 are spaced apart from each other in the first direction L. In this case, the signal lines 7 and the touch lines 6 satisfy at least one of the following three conditions: (1) the signal lines 7 and the touch lines 6 are disposed in the same layer; (2) the thickness of the signal line 7 is the same as the thickness of the touch line 6; and (3) the material of the signal line 7 is the same as the material of the touch line 6. The embodiments of the present disclosure take the case where the signal lines 7 and the touch lines 6 satisfy the three conditions at the same time as an example, in this case, the signal lines 7 and the touch lines 6 may be manufactured by using a single patterning process. On this basis, in the case that the signal lines 7 and the support members may be also manufactured by using a single patterning process, the signal lines 7, the touch lines 6, and the support members may be manufactured by using a single patterning process. For example, the first support members 8, the second support members 9, the third support members 11, the signal lines 7, and the touch lines 6 may be manufactured by using a single patterning process.

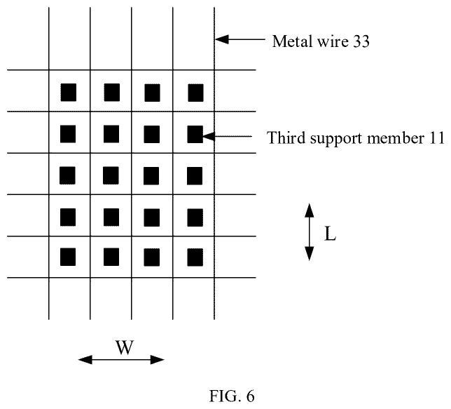

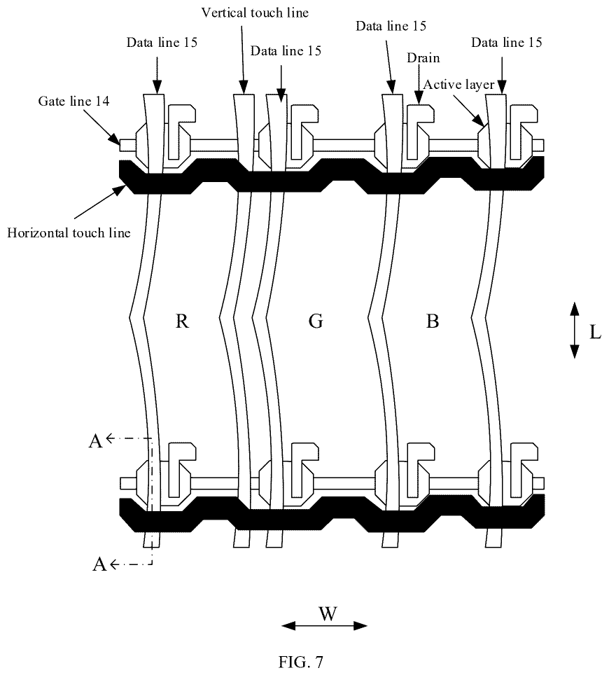

In some embodiments, at least one sealing region (such as the first sealing region 3, the second sealing region 4, and/or the third sealing regions 10) where the support members are disposed is provided with overlapping metal wires, and the metal wires are configured to transmit signals. The embodiments of the present disclosure do not limit the signals transmitted by the metal wires. An orthographic projection of each of the support members on the base substrate is disposed outside an orthographic projection of an overlapping portion of the metal wires on the base substrate. As shown in FIG. 6, overlapping metal wires 33 are provided in the third sealing region 10, and an orthographic projection of each of the third support members 11 on the base substrate 1 is disposed outside an orthographic projection of an overlapping portion of the metal wires 33 on the base substrate 1. It can be seen that the third support members 11 and the metal wires 33 are spaced apart from each other.

The metal wire is disposed in the same layer as the gate line or the data line in the display region 2 for transmitting signals. The side of the metal wire away from the base substrate is covered with a passivation layer, and the passivation layer is provided with a support member. The orthographic projection of the support member on the base substrate is disposed outside the orthographic projection of the overlapping portion of the metal wires on the base substrate; that is, the support member is not provided at the overlapping portion of the metal wires. Since the height of the sealant at the overlapping portion has already been elevated by a relatively high margin, such design can prevent the sealant at the overlapping portion from being overly elevated, thereby making the cell gap in the non-display region more uniform.

In some embodiments, as shown in FIG. 7, the array substrate includes a vertical touch line extending in the first direction L (the vertical touch line is not shown in the drawings of the aforementioned embodiments) and horizontal touch lines extending in the second direction W. The touch lines 6 in the aforementioned embodiments are the horizontal touch lines. As can be seen from FIG. 7, the data lines 15 extend in the first direction L, the gate lines 14 extend in the second direction W. One pixel unit includes a red sub-pixel R, a green sub-pixel G, and a blue sub-pixel B, and one vertical touch line is provided in one pixel unit. For example, one vertical touch line is provided between the red sub-pixel R and the green sub-pixel G, and the vertical touch line and the data line 15 may be manufactured by using the same process, such that the thickness of the display device is reduced. One horizontal touch line is provided in one pixel unit, and the horizontal touch line may overlap with a gate common line (the gate common line is not shown in FIG. 7, the gate common line is connected to a common electrode in the sub-pixel, and the common electrode is not shown in FIG. 7), thereby improving the aperture ratio.

In the embodiments of the present disclosure, the signal lines 7 have the same thickness as the horizontal touch lines (the touch lines 6). Compared with the design of reducing the thickness of the signal lines 7 in a jumper in the related art, the resistance of the signal lines 7 can be reduced. Tests show that the sheet resistance of the signal line decreases from 0.12 ohms to 0.02 ohms, which improves the touch sensitivity. In addition, the signal line 7 and the horizontal touch line may be manufactured in the same layer by using the same process. For example, both the signal line 7 and the horizontal touch line are manufactured by using a copper wire with the thickness of 9000 angstroms, which can simplify the manufacturing process.

Optionally, the array substrate further includes a common line disposed in the non-display region on the base substrate, and the touch lines 6 are connected to the common line. For example, the touch lines 6 are connected to the aforementioned signal lines 7 through the common line. The position of the common line in the non-display region may vary. The following briefly describes two of the cases.

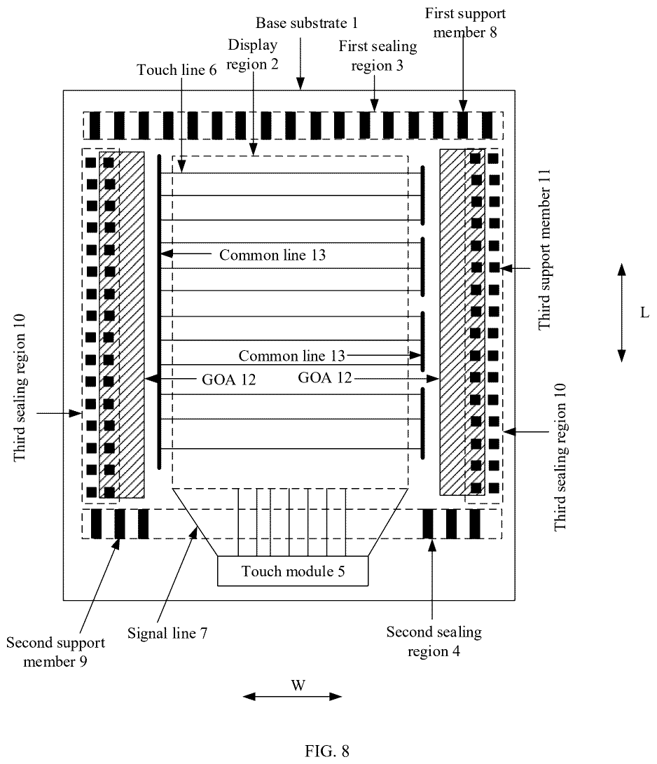

Case (1): As shown in FIG. 8, the array substrate includes a common line 13 extending in the first direction L between the third sealing region 10 and the display region 2. The end of each of the plurality of touch lines 6 close to the common line 13 is connected to the common line 13. Since the array substrate is provided with two third sealing regions 10, the array substrate is provided with a common line 13 between each third sealing region 10 and the display region 2.

Optionally, the common line 13 between one third sealing region 10 (such as the third sealing region 10 on the left side in FIG. 8) and the display region 2 is an entire line, and the common line 13 between the other third sealing region 10 (such as the third sealing region 10 on the right side in FIG. 8) and the display region 2 includes a plurality of line segments. The plurality of line segments are arranged in the first direction L and extend in the first direction L. The plurality of touch lines 6 are divided into a plurality of groups, the plurality of groups of touch lines 6 are in a one-to-one correspondence with the plurality of line segments, and each line segment is connected to a corresponding group of touch lines 6. In FIG. 8, the case where each group of touch lines 6 includes three touch lines 6 is taken as an example.

In the case that the touch lines 6 are connected to the aforementioned signal lines 7 through the common lines, the common lines are further connected to the signal lines 7 (the connection relationship is not shown in FIG. 8).

With further reference to FIG. 8, the array substrate further includes a gate drive circuit (GOA) 12 disposed on a side of the common line 13 away from the display region 2, and at least a portion of an orthographic projection of the GOA 12 on the base substrate 0 is disposed in the third sealing region 10. In this case, the GOA 12 overlaps with the third sealing region 10, which can improve the space utilization rate. In FIG. 8, a case where a portion of the orthographic projection of the GOA 12 on the base substrate 0 is disposed in the third sealing region 10 is taken as an example. It can be understood that an entire orthographic projection of the GOA 12 on the base substrate 0 may be disposed in the third sealing region 10.

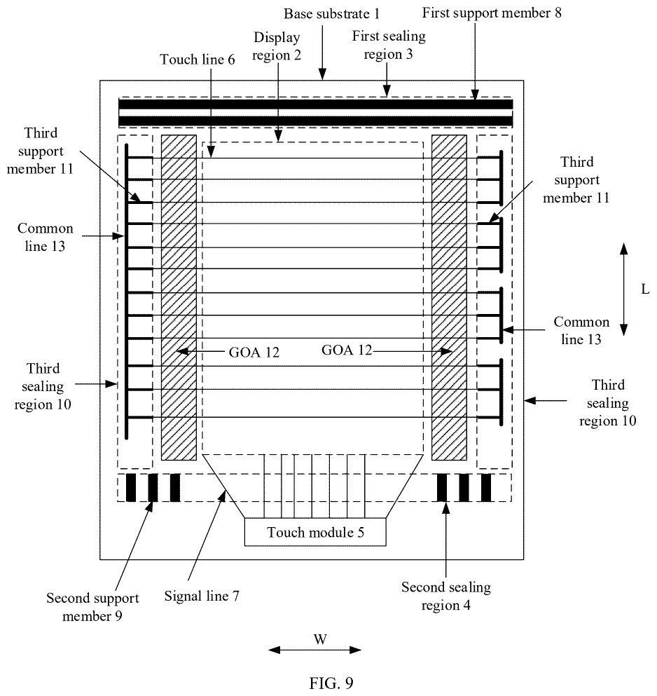

Case (2): As shown in FIG. 9, the array substrate includes: common lines 13 extending in the first direction L in the third sealing regions 10. A plurality of support members (third support members 11) are distributed in each of the third sealing regions 10, and the plurality of third support members 11 are spaced apart from each other in the first direction L and extend in the second direction W. In each third sealing region 10, the plurality of third support members 11 are disposed between the common line 13 and the display region 2, the plurality of third support members 11 in the third sealing region 10 are in a one-to-one correspondence with the plurality of touch lines 6, and in the third sealing region 10, the end of each of the plurality of third support members 11 close to the display region 2 is connected to the corresponding touch line 6, and the end of each of the plurality of third support members 11 away from the display region 2 is connected to the common line 13.

Since the array substrate is provided with two third sealing regions 10, the array substrate is provided with a common line 13 in each third sealing region 10. Optionally, the common line 13 in one third sealing region 10 (such as the third sealing region 10 on the left side in FIG. 9) is an entire line, and the common line 13 in the other third sealing region 10 (such as the third sealing region 10 on the right side in FIG. 9) includes a plurality of line segments. The plurality of line segments are arranged in the first direction L and extend in the first direction L. The plurality of touch lines 6 are divided into a plurality of groups, the plurality of groups of touch lines 6 are in a one-to-one correspondence with the plurality of line segments, and each line segment is connected to a corresponding group of touch lines 6. In FIG. 9, the case where each group of touch lines 6 includes three touch lines 6 is taken as an example.

In the case that the touch lines 6 are connected to the aforementioned signal lines 7 through the common lines, the common lines are further connected to the signal lines 7 (the connection relationship is not shown in FIG. 9).

With further reference to FIG. 9, the array substrate further includes GOAs disposed between the display region 2 and the third sealing regions 10.

Compared FIG. 8 with FIG. 9, it can be seen that in FIG. 9, the GOAs move toward the display region, and the touch lines 6 extend to the third sealing regions 10 to form the third support members 11 in the third sealing regions 10. In this way, the manufacturing process of the third support members 11 can be simplified, such that the third support members 11 and the touch lines 6 may be manufactured by using the same process, which is more convenient.

In some embodiments of the present disclosure, a display device is provided. The display device is a display panel, a smart phone, a tablet computer, or the like.

The display device according to the embodiments of the present disclosure includes: an array substrate and a color filter substrate, and a liquid crystal layer and a sealant disposed between the array substrate and the color filter substrate. The array substrate is any array substrate according to the embodiments of the present disclosure, and the sealant is disposed in the first sealing region, the second sealing region, and the third sealing regions of the array substrate. The sealant is used to seal the space between the array substrate and the color filter substrate. The liquid crystal layer is disposed in the space.

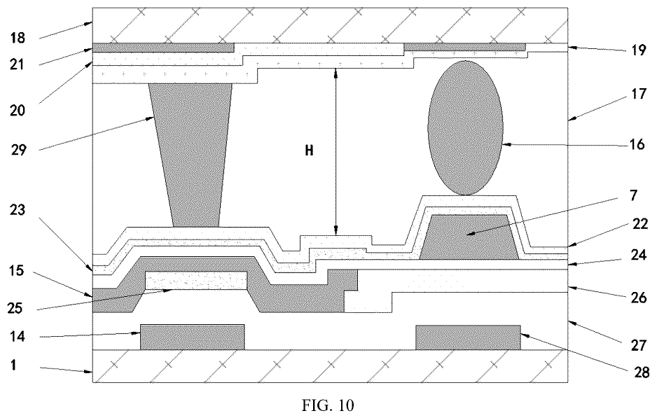

Exemplarily, as shown in FIG. 10 (a cross section of the display device shown in FIG. 10 is a cross section of a position where AA is disposed in FIG. 7), the display device includes an array substrate, a liquid crystal layer 17, and a color filter substrate which are stacked in sequence. The array substrate is the array substrate according to any one of the above embodiments, a sealant 16 is disposed between the array substrate and the color filter substrate, and the sealant 16 is disposed in the first sealing region, the second sealing region, and the third sealing regions.

As shown in FIG. 10, in the array substrate, a gate line 14 and a gate common line 28 are provided on the base substrate 1; a side of the gate line 14 and a side of the gate common line 28 that are away from the base substrate 1 are covered with an insulating layer 27; a side of the insulating layer 27 away from the base substrate 1 is provided with an active layer 25 and a pixel electrode 26; a side of the active layer 25 away from the base substrate 1 is provided with a data line 15; a side of the data line 15 and a side of the pixel electrode 26 that are away from the base substrate 1 are covered with a second passivation layer 24; a side of the second passivation layer 24 away from the base substrate 1 is provided with a signal line 7; a side of the signal line 7 away from the base substrate 1 is covered with a first passivation layer 23; a side of the first passivation layer 23 away from the base substrate 1 is provided with a common electrode layer 22; and the aforementioned 7-mask process is used to sequentially form the gate line 14, the active layer 25, the pixel electrode 26, the data line 15, the signal line 7, the first passivation layer 23, and the common electrode layer 22.

In the color filter substrate, a color filter layer 20 and a black matrix 21 are provided on a side of a substrate 18 of the color filter substrate close to the liquid crystal layer 17; and an alignment layer 19 is provided on a side of the color filter layer 20 close to the liquid crystal layer 17.

The array substrate further includes a spacer 29 disposed between the color filter substrate and the array substrate, the spacer 29 is disposed on a side of the data line 15 away from the base substrate 1, and the sealant 16 is disposed on a side of the signal line 7 away from the base substrate 1.

The display device has a simple structure and is convenient to manufacture, and can improve the cell gap uniformity (for example, H in FIG. 10) of a non-display region. This avoids liquid crystal leakage and water vapor intrusion, and also avoids yellowing of a screen, thus improving the quality of the displayed image.

Those of ordinary skill in the art should understand that the discussion of any of the above embodiments is only exemplary, and is not intended to imply that the scope of the present disclosure (including the claims) is limited to these examples. Under the idea of the present disclosure, the technical features in the above embodiments or different embodiments may also be combined, the steps may be implemented in any order, and there are many other variations of different aspects of the embodiments of the present disclosure as described above, which are not provided in detail for the sake of brevity.

In the embodiments of the present disclosure, “film” and “layer” are interchanged. For example, the “conductive layer” is sometimes replaced with a “conductive film”. Similarly, the “insulating film” is replaced with the “insulating layer” in some cases. The scale of the drawings in the embodiments of the present disclosure may be used as a reference in the actual process, but is not limited thereto. For example, a width-to-length ratio of the channel, and the thickness and spacing of each film layer may be adjusted based on an actual requirement. The number of pixels in the array substrate and the number of sub-pixels in each pixel are not limited to the numbers shown in the drawings, the drawings described in the embodiments of the present disclosure are only schematic structural diagrams, and a manner in the embodiments of the present disclosure is not limited to the shapes or values shown in the drawings.

In the embodiments of the present disclosure, a triangle, a rectangle, a trapezoid, a pentagon, a hexagon, or the like is not strictly limited, and may be an approximate triangle, a rectangle, a trapezoid, a pentagon, a hexagon, or the like. There may be some small deformations caused by a tolerance, and there may be a chamfer, an arc, a deformation, and the like.

In addition, in the case that details are set forth to describe exemplary embodiments of the present disclosure, it will be apparent to those skilled in the art that the embodiments of the present disclosure may be implemented without these details or with changes in these details. Accordingly, the description is to be regarded as illustrative rather than restrictive.

In some embodiments of the present disclosure, a method for manufacturing an array substrate is provided. The method includes: forming a plurality of touch lines, a plurality of signal lines, a touch module, and support members on a base substrate. The base substrate includes a display region, a first sealing region, a second sealing region, and two third sealing regions. The first sealing region and the second sealing region are disposed on two opposite sides of the display region in a first direction, the two third sealing regions are disposed on two opposite sides of the display region in a second direction, and the first direction is perpendicular to the second direction; the touch modules are disposed on a side of the second sealing region away from the display region, the touch lines extend in the second direction in the display region, the signal lines are disposed in the second sealing region, and the touch lines are connected to the touch module through the signal lines; and the support members are distributed in the first sealing region and/or the third sealing regions, the support members and the signal lines are disposed in a same layer, and in a direction perpendicular to the base substrate, a difference between the thickness of the support member and the thickness of the signal line is less than the thickness of the signal line.

For example, the touch lines 6 are formed in the display region 2 of the base substrate 1, first support members 8 are formed in the first sealing region 3 of the base substrate 1, the signal lines 7 and the second support members 9 are formed in the second sealing region 4 of the base substrate 1, and third support members 11 are formed in the third sealing regions 10 of the base substrate 1. The touch module 5 is formed on a side of the second sealing region 4 of the base substrate 1 away from the display region 2.

For the array substrate manufactured by using the method according to the embodiments of the present disclosure, refer to any array substrate according to the aforementioned embodiments. Details are not described in the embodiments of the present disclosure.

In some embodiments, the support members and the signal lines may be manufactured by using a single patterning process. In some embodiments, the signal lines and the touch lines 6 may be also manufactured by using a single patterning process. In some embodiments, the support members, the signal lines, and the touch lines 6 may be all manufactured by using a single patterning process.

The “patterning process” described in the embodiments of the present disclosure includes processes such as photoresist coating, mask exposure, development, etching, and photoresist stripping for a metal material, an inorganic material, or a transparent conductive material, and includes processes such as organic material coating, mask exposure, and development for an organic material. Any one or more of sputtering, evaporation, and chemical vapor deposition are used for deposition, any one or more of spray coating, spin coating, and inkjet printing are used for coating, and any one or more of dry etching and wet etching are used for etching. This is not limited herein.

Those of ordinary skill in the art should understand that the discussion of any of the above embodiments is only exemplary, and is not intended to imply that the scope of the present disclosure (including the claims) is limited to these examples. Under the idea of the present disclosure, the technical features in the above embodiments or different embodiments may also be combined, the steps may be implemented in any order, and there are many other variations of different aspects of the embodiments of the present disclosure as described above, which are not provided in detail for the sake of brevity.

In addition, to simplify the description and discussion, and in order not to make the embodiments of the present disclosure difficult to understand, well-known power/ground connections with other components may or may not be shown in the provided drawings. In the case that specific details are set forth to describe exemplary embodiments of the present disclosure, it will be apparent to those skilled in the art that the embodiments of the present disclosure are implemented without these specific details or with changes in these specific details. Accordingly, the description is to be regarded as illustrative rather than restrictive.

Although the present disclosure has been described with reference to specific embodiments of the present disclosure, many alternatives, modifications, and variations of these embodiments are obvious to those of ordinary skill in the art based on the aforementioned description. Embodiments of the present disclosure are intended to cover all such alternatives, modifications, and variations that fall within the broad scope of the appended claims. Any omissions, modifications, equivalent substitutions, improvements, and the like made within the spirit and principle of the embodiments of the present disclosure should fall within the protection scope of the present disclosure.

1. An array substrate, comprising: a base substrate, a plurality of touch lines, a plurality of signal lines, a touch module, and support members; wherein
the base substrate comprises a display region, a first sealing region, a second sealing region, and two third sealing regions, the first sealing region and the second sealing region are disposed on two opposite sides of the display region in a first direction, the two third sealing regions are disposed on two opposite sides of the display region in a second direction, and the first direction is perpendicular to the second direction; the touch module is disposed on a side of the second sealing region away from the display region, the touch lines extend in the second direction in the display region, the signal lines are disposed in the second sealing region, and the touch lines are connected to the touch module through the signal lines; and
the support members are distributed in the first sealing region and/or the two third sealing regions, the support members and the signal lines are disposed in a same layer, and in a direction perpendicular to the base substrate, a difference between a thickness of each of the support members and a thickness of each of the signal lines is less than the thickness of the signal line.

2. The array substrate according to claim 1, wherein a ratio of the thickness of each of the support members to the thickness of each of the signal lines is greater than 0.8 and less than 1.2.

3. The array substrate according to claim 2, wherein the thickness of each of the support members is as same as the thickness of each of the signal lines.

4. The array substrate according to claim 1, wherein a material of each of the support members is as same as a material of each of the signal lines.

5. The array substrate according to claim 1, wherein an area ratio of the support members in the first sealing region and an area ratio of each of the support members in the third sealing regions are all greater than 0.2 and less than 1.

6. The array substrate according to claim 1, wherein the support members are further distributed in the second sealing region, and an orthographic projection of each of the support members on the base substrate is disposed outside an orthographic projection of each of the signal lines on the base substrate.

7. The array substrate according to claim 6, wherein in the second sealing region, the support members are distributed on two sides of the signal lines.

8. The array substrate according to claim 6, wherein an area ratio of the support members in the second sealing region is greater than 0.1 and less than 0.6.

9. The array substrate according to claim 1, wherein a plurality of the support members are provided and spaced apart from each other in at least one sealing region where the support members are disposed.

10. The array substrate according to claim 9, wherein the support members are arranged in an array in the at least one sealing region.

11. The array substrate according to claim 1, wherein the support members in the first sealing region are strip-shaped, extend in the second direction, and are spaced apart in the first direction.

12. The array substrate according to claim 1, wherein the support members in the first sealing region are strip-shaped, extend in the first direction, and are spaced apart in the second direction.

13. The array substrate according to claim 6, wherein the support members in the second sealing region are strip-shaped, extend in the first direction, and are spaced apart in the second direction.

14. The array substrate according to claim 1, further comprising: common lines, each of the common lines extends in the first direction in each of the two third sealing regions; a plurality of the support members are distributed in each of the two third sealing regions, and the plurality of support members are spaced apart in the first direction and extend in the second direction; the plurality of support members in each of the two third sealing regions are disposed between each of the common lines and the display region; and
the plurality of support members are in a one-to-one correspondence with the plurality of touch lines, and in each of the two third sealing regions, an end of each of the plurality of support members close to the display region is connected to a corresponding touch line, and an end of each of the plurality of support members away from the display region is connected to each of the common lines.

15. The array substrate according to claim 14, further comprising gate drive circuits, and each of the gate drive circuits is disposed between the display region and each of the two third sealing regions.

16. The array substrate according to claim 1, further comprising: common lines, each of the common lines extends in the first direction between each of the two third sealing regions and the display region; and an end of each of the plurality of touch lines close to each of the common lines is connected to each of the common lines.

17. The array substrate according to claim 16, further comprising: gate drive circuits, each of the gate drive circuits is disposed on a side of each of the common lines away from the display region, and at least a portion of an orthographic projection of each of the gate drive circuits on the base substrate is disposed in each of the two third sealing regions.

18. The array substrate according to claim 1, wherein the plurality of touch lines extend in the second direction and are spaced apart in the first direction; and
the signal lines and the touch lines satisfy at least one of following conditions:
the signal lines and the touch lines are disposed in a same layer;
the thickness of each of the signal lines is as same as a thickness of each of the touch lines; and
the material of each of the signal lines is as same as a material of each of the touch lines.

19. The array substrate according to claim 1, wherein overlapping metal wires are provided in the at least one sealing region in which the support members are disposed, and an orthographic projection of each of the support members on the base substrate is disposed outside an orthographic projection of an overlapping portion of the metal wires on the base substrate.

20. A display device, comprising: an array substrate and a color filter substrate, and a liquid crystal layer and a sealant disposed between the array substrate and the color filter substrate; wherein
the array substrate is the array substrate as defined in claim 1, and the sealant is disposed in the first sealing region, the second sealing region, and the two third sealing regions of the array substrate.
